(19) United States
(12) Patent Application Publication
(10) Pub. No.: US 2009/0184740 A1
(43) Pub. Date: Jul. 23, 2009

(54) Phase-Locked Loop Circuit with Accelerated Frequency Acquisition

(75) Inventor: Akmarul Ariffin SALLEH, Penang (MY)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 12/017,052

(22) Filed: Jan. 21, 2008

(51) Int. Cl. H03L 7/085; H03L 7/08

(52) U.S. Cl. 327/157

(57) ABSTRACT

Frequency acquisition is accelerated in a phase-locked loop circuit. A duration of time for sinking current from or sourcing current to a loop filter is calculated in order to accelerate frequency acquisition of a reference frequency of a reference signal and a feedback frequency of a feedback signal fed back from a controlled oscillator when the feedback signal frequency is changed or frequency of the reference signal is changed by a predetermined amount. The feedback signal frequency is changed or frequency of the reference signal is changed by the predetermined amount. Sinking current from or sourcing current to a loop filter electrically connected to the controlled oscillator for the duration of time is performed resulting in the reduction of the time for frequency acquisition.

### BACKGROUND OF THE INVENTION

A phase-locked loop (PLL) is a closed-loop feedback control system that generates and outputs a signal in relation to the frequency and phase of an input (“reference”) signal. A phase-locked loop circuit responds to both the frequency and the phase of the input signals, automatically raising or lowering the frequency of a controlled oscillator until it is matched to the reference in both frequency and phase.

This type of circuit is widely used in radio, telecommunications, computers and other electronic applications where it is desired to stabilize a generated signal or to detect signals in the presence of noise. Since an integrated circuit can hold a complete phase-locked loop building block, the technique is widely used in modern electronic devices, with signal frequencies from a fraction of a cycle per second up to many gigahertz.

Prior-art phase-locked loop circuits can have problems with locking to the correct frequency if the target frequency or phase is too far off from that of the controlled oscillator, which might be a voltage-controlled oscillator. Also, once the phase-locked loop is in lock, it can fall out of lock if the voltage-controlled oscillator signal goes more than a certain amount off in frequency. And even when the phase-locked loop is in lock, there is steady state phase error. For instance, a mixer phase detector introduces a 90-degree phase shift.

One way around some of these problems is using an active rather than a passive loop filter. In an active loop filter an op-amp or transistor is often used. However, op-amps and transistors have the disadvantage of adding cost, noise and size to the phase-locked loop circuit. Still, active loop filters using op-amps are often necessary when the VCO tuning voltage needs to be higher than a charge pump can supply in a charge pump phase-locked loop circuit.

A charge pump phase-locked loop circuit adds a charge pump to the phase-locked loop circuit. The charge pump converts a voltage output by a phase detector into a current, which is then converted into a voltage by a loop filter and supplied to the control input of a voltage-controlled oscillator. The voltage-controlled oscillator then converts the control voltage at its control input into an VCO output frequency. The VCO output frequency is fed-back to the phase detector, possibly after passing through a frequency divider. The phase detector compares the feedback signal's frequency with that of a reference signal's frequency to output the voltage to the charge pump. The charge pump phase-locked loop circuit provides the advantage of being able to lock to any frequency, regardless of how far off it is initially in frequency, and does not have a steady state phase error.

A problem with the charge-pump phase-locked loop circuit is that for optimum phase noise performance, the loop bandwidth needs to be optimized which requires the charge-pump current to be small. But the smaller the charge-pump current the longer the frequency acquisition time.

Thus, both charge-pump and non-charge-pump phase-locked loop circuits have a problem with the speed of the frequency acquisition process. The frequency of the phase-locked loop circuit is changed from one frequency to another by changing the divide-by-factor “N” of the frequency divider. Alternatively, the frequency of the phase-locked loop circuit can be changed from one frequency to another by changing the frequency of the reference frequency. The frequency-acquisition process is the process of the phase-locked loop acquiring a frequency to bring the reference frequency and feedback signal frequency within a certain frequency error of each other. It can also be considered the process of obtaining a frequency lock. When it is desired to change the frequency of phase-locked loop circuit from one frequency to another, it will take some time to regain the frequency lock after changing the divide-by-factor or reference frequency. In other words, the frequency-acquisition process takes some time. In many applications it is desirable to minimize this time for the frequency-acquisition process.

U.S. Pat. No. 4,115,745 entitled “Phase Lock Speed-Up Circuit” and granted to William F. Egan on Sep. 19, 1978, and “Frequency Synthesis by Phase Lock”, Second Edition, Section 10.4.6.4 “Current Injection”, pgs 477-480, by William F. Egan, published in 1999, both describe circuits for speeding up the frequency-acquisition process by injecting direct current into the loop filter. However, this method requires varying the amplitude of the injected direct current and does not minimize the cost and the components used.

It would be desirable to provide a simple and cost effective phase-locked loop circuit having accelerated frequency acquisition.

### SUMMARY OF THE INVENTION

The present invention provides a simple and cost effective phase-locked loop circuit having accelerated frequency acquisition.

In general terms, an embodiment of the present invention provides a method for accelerating frequency acquisition in a phase-locked loop circuit by performing the steps of: calculating a duration of time for sinking current from or sourcing current to a loop filter in order to accelerate frequency acquisition of a reference frequency of a reference signal and a feedback frequency of a feedback signal fed back from a controlled oscillator when the feedback signal frequency is changed or frequency of the reference signal is changed by a predetermined amount; changing the feedback signal frequency or frequency of the reference signal by the predetermined amount; and sinking current from or sourcing current to a loop filter electrically connected to the controlled oscillator for the duration of time to accelerate the frequency acquisition of the reference frequency and the feedback frequency.

### BRIEF DESCRIPTION OF THE DRAWINGS

Further preferred features of the invention will now be described for the sake of example only with reference to the following figures, in which:

FIG. 1 shows a schematic diagram of a phase-locked loop circuit having accelerated frequency acquisition of the present invention.

FIG. 2 shows a more schematic diagram of the lock accelerator block of FIG. 1.

FIG. 3 shows an implementation of the two current sources and two switches of FIG. 2.

FIG. 4(A) shows an exemplary graph of the phase-locked loop circuit ramping up from 1.6 GHz to 3.2 GHz when the accelerated frequency acquisition is not used.

FIG. 4(B) shows an exemplary graph of the phase-locked loop circuit ramping down from 3.2 GHz to 1.6 GHz when the accelerated frequency acquisition is not used.

FIG. 5 shows a graph of the Δt calculated for a “High” logic state input into the lock accelerator such that the switch SW1 is closed and the switch SW2 is open causing Iacc1 to source current to the loop filter.

FIG. 6 illustrates frequency acquisition improvement for a ramp up from 1.6 GHz to 3.2 GHz.

FIG. 7 shows a flowchart for a method for accelerating frequency acquisition in a phase-locked loop circuit of the present invention.

### DETAILED DESCRIPTION

The present invention provides a simple and cost effective phase-locked loop circuit having accelerated frequency acquisition.

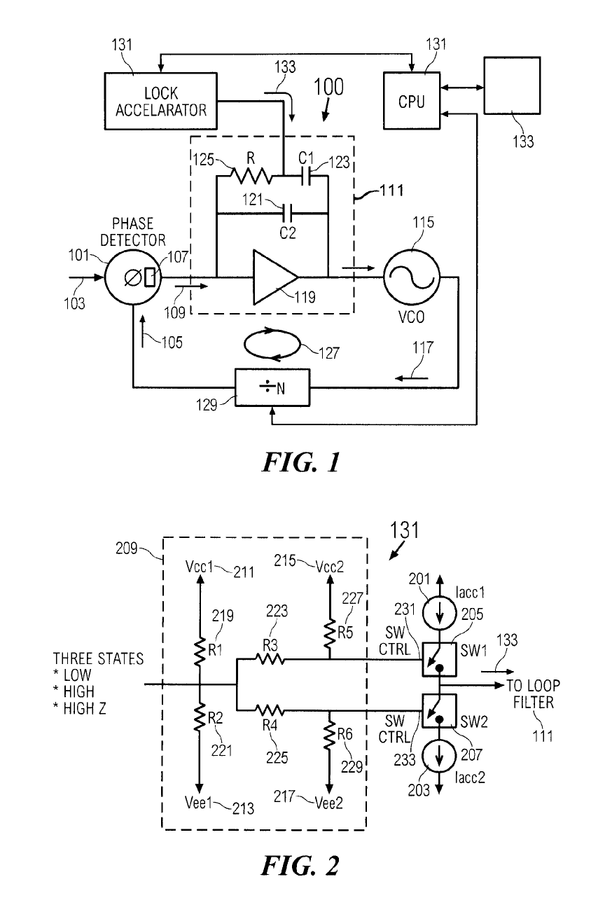

FIG. 1 shows a schematic diagram of a phase-locked loop circuit having accelerated frequency acquisition 100 of the present invention. A phase detector 101 receives two signals, a reference signal 103 and a feedback signal 105. The phase detector 101 outputs a phase detector output signal 109 indicative of whether the frequency of the feedback signal 105 needs to increase or decrease.

The phase detector 101 can be a phase frequency detector (PFD), for example, and might include a charge pump 107. Without the charge pump 107, the phase detector will output a voltage. When the charge pump 107 is included the phase detector output signal 109 will be a current. The charge pump 107 can either source the current of the phase detector output signal 109 into a loop filter 111 or sink the current of the phase detector output signal 109 from the loop filter 111, depending on whether the feedback signal 105 needs to increase or decrease for frequency acquisition of the reference frequency of the reference signal 103 and the frequency of a voltage-controlled oscillator output signal 117 of a voltage-controlled oscillator 115. More generally the voltage-controlled oscillator can be any type of controlled oscillator. When the charge pump 107 is included, the phase detector output signal 109 is the charge pump current.

The loop filter 111 is a low-pass filter which smoothes out abrupt changes in a tuning voltage 113 of the voltage-controlled oscillator 115 and helps create stable system. The loop filter 111 can also help to filter reference frequency feed-through from the phase detector 101. The loop filter 111 can including passive components such as capacitors 121, 123 and a resistor 125 in a low-pass filter arrangement. If an active filter is desired than an active component such as an op-amp 119 can be incorporated. Other arrangements of passive components and different types of active components can also be used in the design of the loop filter 111 as is known in the art.

The loop filter 111 converts the detector output signal 109 into a tuning voltage 113 and supplies it to the voltage-controlled oscillator 115. In a preferred embodiment the phase detector output signal 109 is a current.

The loop filter 111 and the voltage-controlled oscillator 115 can be placed in a negative feedback loop 127 in a closed-loop configuration. There may be a frequency divider 129 in the feedback path or in the reference path, or both, in order to make the frequency of the controlled oscillator output signal 117 an integer multiple of the frequency of the reference signal 103. A non-integer multiple of the reference frequency can be created by replacing the simple divide-by-N counter in the feedback path with a programmable pulse swallowing counter. This technique is usually referred to as a fractional-N synthesizer or fractional-N PLL. The frequency divider 129 converts the frequency of controlled oscillator output signal 117 to output the feedback signal 105 to the phase detector 101. The frequency of the feedback signal 105 and the controlled oscillator output signal 117 is the same if the divide-by factor used by the frequency divider 129 is “unity” or when the frequency divider 129 is not put in the circuit at all.

A simplified explanation of the function of an embodiment of the invention using the parts of the circuit 100 described thus far is now provided. The voltage-controlled oscillator 115 generates the periodic output signal 117. Assume that initially the signal 117 is at nearly the same frequency as the reference signal 103. Then, if the phase from the oscillator 115 falls behind that of the reference 103, the phase detector 101 changes the tuning voltage 113 of the oscillator 115, so that it speeds up. Likewise, if the phase creeps ahead of the reference 103, the phase detector 101 changes the tuning voltage 113 to slow down the oscillator 115.

The two inputs 103, 105 of the phase detector 101 are the reference input 103 and the feedback 105 from the voltage-controlled oscillator 115. The phase detector 101 output controls the voltage-controlled oscillator 115 to make the phase difference between the two inputs constant, thereby creating a negative feedback system.

FIG. 1 also shows a lock accelerator block 131 for accelerating the frequency acquisition of the phase-locked loop circuit 100. The lock accelerator block 131 provides a frequency acquisition acceleration current 133 sinking current from or sourcing current to the loop filter 111.

FIG. 2 shows a more detailed schematic diagram of the lock accelerator block 131. The frequency acquisition acceleration current 133 of FIG. 1 is also shown in FIG. 2 and is supplied by either the current source Iacc1 201 or Iacc2 203. When a switch SW1 205 is closed, and a switch SW2 207 is open, the current source Iacc1 201 sources current to the loop filter 111. When the switch SW2 207 is closed and the switch SW1 205 is open, the current source Iacc2 203 sinks current from the loop filter 111. Also, when both of the switches SW1 205 and SW2 207 are open, there will be no frequency acquisition acceleration current 133 supplied to the loop filter 111.

The control of the switches SW1 205 and SW2 207 is elegantly implemented with minimum components and low cost using the resistance network 209. The resistance network 209 provides a switch control voltage 231 for controlling the switch SW1 205 and a switch control voltage 233 for controlling the switch SW2 207. Voltages Vcc1 211, Vee1 213, Vcc2 215 and Vee2 217 provide voltage to the resistances 219, 221, 223, 225, 227, 229 to generate the switch control voltages 231, 233. The voltages are turned on and off in three different combinations to provide three states of logic, Low, High and High Z (tri-stated) which can be easily implemented on a Field Programmable Gate Array (“FPGA”). The switch conditions based on the inputs are:

| Input | SW1 205 | SW2 207 |
|---|---|---|
| Low | ON | OFF |
| High | OFF | ON |
| High Z | OFF | OFF |

When the input is Low, the current from the current source Iacc1 201 is sourced into the loop filter 111 and this causes the voltage tuning voltage 113 of the voltage-controlled oscillator 115 to go lower, in a ramp fashion. The slope of the ramp can be easily modified by changing the value of Iacc1 201. When the input is High, the current from the current source Iacc2 203 is sinked out from the loop filter 111 and this causes the voltage tuning voltage 113 of the voltage-controlled oscillator 115 to go higher, in a ramp fashion. Here the slope of the ramp can be modified by changing the value of Iacc2 203. Either sourcing or sinking current will help the voltage tuning voltage 113 of the voltage-controlled oscillator 115 achieve the desired voltage much more quickly. Once the tuning voltage 113 of the voltage-controlled oscillator 115 is close to the desired voltage, both of the current sources are disconnected from the loop filter 111. This is achieved by setting the input to High Z with both of the switches SW1 205 and SW2 207 set to open.

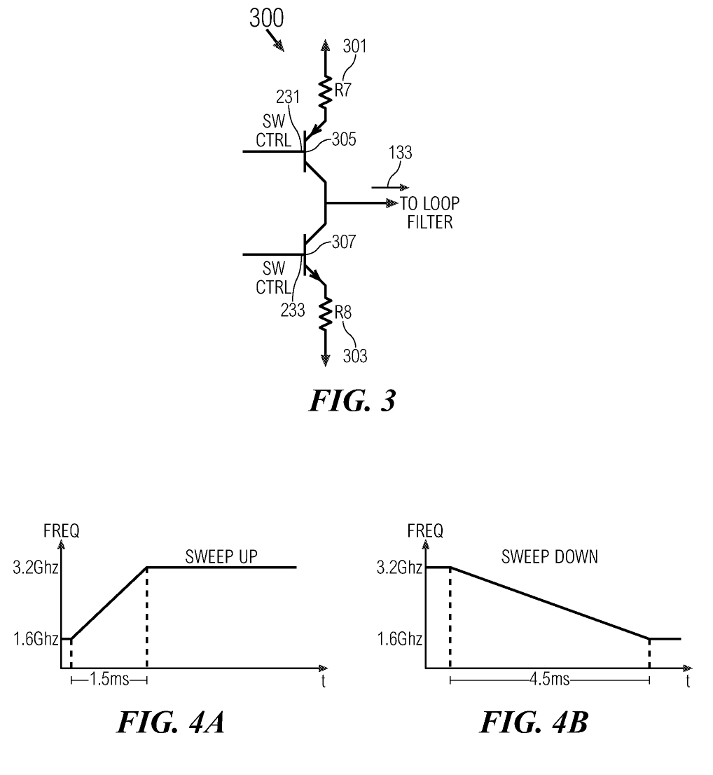

The two current sources 201, 203 and two switches 205, 207 can be implemented by the two resistors R7 301 and R8 303 and two Bipolar Junction Transistors (“BJT's”) 305, 307 of FIG. 3. The resistors R7 301 and R8 303 set the values of the current sources represented by Iacc1 201 and Iacc2 203 in FIG. 2. The BJT's 305, 307 are used as the switches SW1 205, SW2 207 of FIG. 2. The values for Iacc1 201 and Iacc2 203 can be set to different values, however, setting them the same has the advantage of making the frequency acquisition performance the same for the forward and reverse sweeps. A forward sweep might be sweeping the phase-locked loop circuit having accelerated frequency acquisition 100 from 1.6 GHz to 3.2 GHz, in which case a reverse sweep would be from 3.2 GHz to 1.6 GHz.

FIG. 4(A) shows an exemplary graph of the phase-locked loop circuit 100 ramping up from 1.6 GHz to 3.2 GHz when the accelerated frequency acquisition is not used. FIG. 4(B) shows an exemplary graph of the phase-locked loop circuit 100 ramping down from 3.2 GHz to 1.6 GHz when the accelerated frequency acquisition is not used.

The present invention achieves a faster ramp-up or ramp-down of the voltage tuning voltage 113 of the voltage-controlled oscillator 115 to accelerate obtaining the desired tuning voltage of the voltage-controlled oscillator 115. If the lock accelerator is taken out, as is the case for the graphs of FIG. 4(A), 4(B), the voltage tuning voltage 113 of the voltage-controlled oscillator 115 will ramp slowly due to the small value of the charge pump current coming from the charge pump 107. The charge pump current is made small in order to achieve the optimum loop bandwidth. When the lock accelerator block 131 is utilized, the voltage tuning voltage 113 is the superposition of the voltage due to the charge pump current (which is the phase detector output signal 109), and the frequency acquisition acceleration current 133 (which is the current Iacc1 201=Iacc2 203 in the above example). The value of Iacc1 and Iacc2 is determined by how fast it is required to ramp between the output frequency change of the voltage-controlled oscillator 115 (i.e. between 1.6 GHz and 3.2 GHz in the example of FIG. 4).

When the phase-locked loop circuit 100 steps from one frequency to another frequency (for example from 1.6 GHz to 3.2 GHz as shown in FIGS. 4(A), 4(B)) the tuning voltage 113 of the voltage-controlled oscillator 115 will need to change from one value to another. To figure out the duration of time to source or sink the current 133 from the lock accelerator block 131, the tuning voltage 113 of the voltage-controlled oscillator 115 needs to be modeled. This can be done easily by measuring the tuning voltage 113 for several frequencies and then using a software program, such as MICROSOFT EXCEL from the MICROSOFT CORPORATION, to generate the equivalent equation as a function of the frequency of the voltage-controlled oscillator output signal 117. Generally, the equation will be a several order polynomial function:

Vtune(Freq)=Aₙ*Freq̂N+Aₙ₋₁*Freq̂(N−1)+ . . . +A₀ (Eq. 1)

The change in the tuning voltage 113 required to step from one frequency to another frequency is then:

ΔVtune=Vtune(Freq_New)−Vtune(Freq_Old) (Eq. 2)

Next, the duration of time Δt required for setting the input of the lock accelerator block 131 to the logic level Low or High is determined. This is the amount of time for closing the switches SW1 205 and SW2 207 or supplying the frequency acquisition acceleration current 133 to the loop filter 111 as described above. This duration of time Δt is calculated by knowing the values for the passive components, such as the capacitors 121, 123 and resistor 125 of the loop filter 111, as well as the values for the charge pump current 109, value of the current source Iacc1 201 or Iacc2 203 and ΔVtune from Eq. 2. The duration of time Δt is then determined from:

Δt=f(R,C1,C2,ΔVtune,charge pump current,Iacc)

Referring again to FIG. 1 for a simple example of this calculation of the duration of time Δt, it is assumed that the resistance of the resistor 125 is small, and the capacitance of the capacitor 121 is very big compared to the capacitance of the capacitor 123. Thus, to simplify this example, the resistor 125 can be ignored since it is small and the capacitor 121 can be ignored since it's capacitance is very large and it is in parallel with the much smaller capacitance of the capacitor 123. In this example only the capacitor 123 remains in the calculations.

When the frequency acquisition acceleration current 133 injected, the voltage across the capacitor 123 will change. The voltage across the capacitor 123 is related to the current 133 as:

I=C×(dv/dt).

Thus, the voltage across the capacitor 123 is related to the current 133 as:

v=(1/C)×∫I×dt.

Since I is a constant current then:

∫Idt=I×Δt

and

v=(1/C)×I×Δt.

Assuming C=1 and I=1 then:

V=Δt.

Thus, if the current I is sourced or sinked from Iacc1 201 or Iacc2 203 for 1 second, the voltage across the capacitor 123 will change by 1 volt from its original value.

By knowing the desired to change in ΔVtune, it can be determined over what duration of time Δt the current 133 must be supplied. More complicated circuits can be similarly analyzed as is well known in the art.

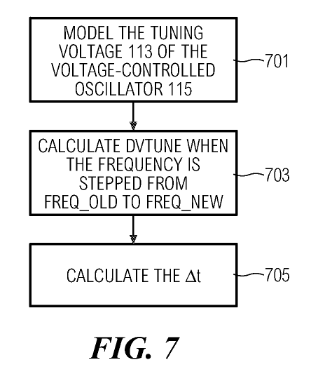

FIG. 7 shows a flowchart for the method for determining Δt to accelerate frequency acquisition in a phase-locked loop circuit 100 of the present invention. The steps are:

701. Model the tuning voltage 113 of the voltage-controlled oscillator 115. (Eq. 1)

703. Calculate ΔVtune when the frequency is stepped from Freq_Old to Freq_New. (Eq. 2)

705. Calculate the Δt. (Eq. 3)

Program code for executing these steps can be stored in a memory 133 and executed by one or more processors 131.

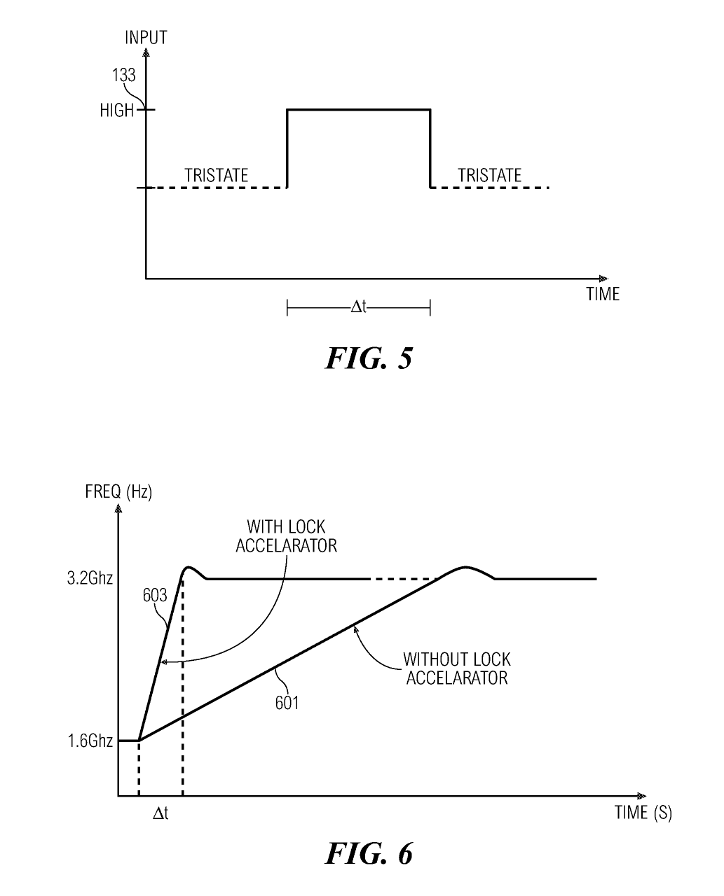

FIG. 5 shows a graph of the Δt calculated for a “High” logic state input into the lock accelerator 131 such that the switch SW1 205 is closed and the switch SW2 207 is open causing Iacc1 201 to source current to the loop filter 111.

By using the lock accelerator 131 of the present invention with the current values Iacc1 201=Iacc2 203=Iacc, rather than requiring the frequency acquisition times of 1.5 ms to ramp up from 1.6 GHz to 3.2 GHz and the 4.5 ms to ramp down from 3.2 GHz to 1.6 GHz, the frequency acquisition times are reduced to 270 micro-seconds for each. FIG. 6 illustrates frequency acquisition improvement for the ramp up from 1.6 GHz to 3.2 GHz. The trace 601 illustrates the 1.5 ms to ramp up from 1.6 GHz to 3.2 GHz without using the lock accelerator 131, while the trace 603 illustrates the frequency acquisition time reduction to 270 micro-seconds to ramp up from 1.6 GHz to 3.2 GHz when the lock accelerator 131 of the present invention is used.

The above calculations, as well as the control of the lock accelerator 131 and the frequency divider 129 can be performed by the one or more processors 131, which can be a microprocessor of a personal computer, for example. The program steps for performing the calculations can be stored in the memory 133 which can be a hard-drive of a personal computer, for example.

In the foregoing specification, the invention has been described with reference to specific exemplary embodiments thereof. The specification and drawings are, accordingly, to be regarded in an illustrative sense rather than a restrictive sense.

1. A method for accelerating frequency acquisition in a phase-locked loop circuit comprising the steps of:
calculating a duration of time for sinking current from or sourcing current to a loop filter in order to accelerate frequency acquisition of a reference frequency of a reference signal and a feedback frequency of a feedback signal fed back from a controlled oscillator;
sinking current from or sourcing current to a loop filter electrically connected to the controlled oscillator for the duration of time to accelerate the frequency acquisition of the reference frequency and the feedback frequency.

2. The method of claim 1, wherein the duration of time is calculated by performing the steps of:
modeling the input into the controlled oscillator as a function of frequency;
calculating the change in input into the controlled oscillator for a desired change in frequency;
calculating the duration of time using the calculated change in input as a parameter and also values of the phase-locked loop as parameters.

3. The method of claim 2, wherein parameters of the phase-locked loop are selected from the set consisting of: loop filter component values, charge pump current level, and levels of the sinking current from or sourcing current to the loop filter.

4. The method of claim 1, wherein the controlled oscillator is a voltage-controlled oscillator and the input is a voltage input.

5. The method of claim 1, further comprising applying the feedback signal and the controlled oscillator reference signal to a phase detector.

6. The method of claim 5, wherein the phase detector includes a charge pump.

7. The method of claim 6, further comprising the step of sinking current from or sourcing current to the loop filter from the charge pump in response to deviations between the reference frequency and the controlled oscillator frequency.

8. The method of claim 1, wherein sinking the current from or sourcing the current to the loop filter is performed by opening and closing at least one switch for the duration of time.

9. The method of claim 1 wherein the current is direct current.

10. A phase-locked loop circuit having accelerated frequency acquisition comprising:
a lock accelerator circuit providing a sink or source current for a duration of time;
a loop filter for receiving the sink or source current for the duration of time and outputting a control signal;
a controlled oscillator for receiving the control signal and outputting an output signal in response to the control signal to provide a feed back frequency;
a processor for calculating the duration of time in order to accelerate frequency acquisition of the reference frequency of a reference signal and the feedback frequency.

11. The phase-locked loop circuit having accelerated frequency acquisition of claim 10, wherein the processor calculates the duration of time by performing the steps of:
modeling the input into the controlled oscillator as a function of frequency;
calculating the change in input into the controlled oscillator for a desired change in frequency;
calculating the duration of time using the calculated change in input as a parameter and also values of the phase-locked loop as parameters.

12. The phase-locked loop circuit having accelerated frequency acquisition of claim 11, wherein parameters of the phase-locked loop are selected from the set consisting of: loop filter component values, charge pump current level, and levels of the sinking current from or sourcing current to the loop filter.

13. The phase-locked loop circuit having accelerated frequency acquisition of claim 10, wherein the controlled oscillator is a voltage-controlled oscillator and the input is a voltage input.

14. The phase-locked loop circuit having accelerated frequency acquisition of claim 10, further comprising a phase detector for comparing the feedback signal and the controlled oscillator reference signal and outputting a signal representative of the difference.

15. The phase-locked loop circuit having accelerated frequency acquisition of claim 14, wherein the phase detector includes a charge pump.

16. The phase-locked loop circuit having accelerated frequency acquisition of claim 15, further comprising the step of sinking current from or sourcing current to the loop filter from the charge pump in response to deviations between the reference frequency and the controlled oscillator frequency.

17. The phase-locked loop circuit having accelerated frequency acquisition of claim 1, further comprising at least one switch opened or closed for the duration of time to supply the sinking or sourced current to the loop filter.

18. The phase-locked loop circuit having accelerated frequency acquisition of claim 1 wherein the current is direct current.
